(19) United States
(12) Patent Application Publication
(10) Pub. No.: US 2025/0341553 A1
(43) Pub. Date: Nov. 6, 2025

(54) SENSOR SYSTEM AND METHOD FOR DETECTING A MECHANICAL CONTACT BETWEEN A MOVING PART AND A NON-MOVING PART OF A POWDER HANDLING DEVICE

(71) Applicant: GEA Process Engineering A/S, Søborg (DK)

(72) Inventors: Kristian Ravnborg Nissen, Søborg (DK); Jon Steffen Larsen, Søborg (DK); Andreas Jauernik Voigt, Søborg (DK); Mads Hjertstedt, Søborg (DK)

(73) Assignee: GEA Process Engineering A/S, Søborg (DK)

(21) Appl. No.: 19/265,772

(22) Filed: Jul. 10, 2025

Related U.S. Application Data
(63) Continuation of application No. PCT/EP2024/072754, filed on Aug. 12, 2024.
(63) Continuation-in-part of application No. 18/036,747, filed on May 12, 2023, now Pat. No. 12,392,743.

(30) Foreign Application Priority Data
Aug. 11, 2023 (EP) 23190988.8

(51) Int. Cl. G01R 25/00

(52) U.S. Cl. CPC G01R 25/005

(57) ABSTRACT

Disclosed is a sensor system for detecting a mechanical contact between a moving part and a non-moving part of a powder handling device, such as a rotary valve. The sensor system comprises an electrical signal source configured to provide a first electric signal, the first electric signal comprising a periodic signal component, which is periodic with a predetermined period and a first electric component having a first electric impedance, wherein the electrical signal source and the first electric component are configured to be electrically connected to the rotating powder handling device so that the first electric component and the rotating powder handling device are connected in series to the electrical signal source. Further disclosed is a powder handling device comprising a sensor system and a method for detecting a mechanical contact between a moving part and a non-moving part of a powder handling device.

### CROSS-REFERENCE TO RELATED APPLICATIONS

This application is a continuation of International Application No. PCT/EP2024/072754, filed Aug. 12, 2024, which claims the benefit of European Patent Application No. 23190988.8, filed Aug. 11, 2023, and a continuation-in-part of U.S. patent application Ser. No. 18/036,747, filed May 12, 2023, which is the 371 National Stage of International Application No. PCT/DK2020/050308, the disclosures of which are incorporated herein by reference in their entireties.

### TECHNICAL FIELD

The present disclosure relates to a sensor system for detecting a mechanical contact between a moving part and a non-moving part of a powder handling device, such as a rotary valve, and a method for the same. The present disclosure further relates to a powder handling device comprising the sensor system.

### BACKGROUND

Typically, powder handling devices are used in handling and/or processing of various types of powders, such as chemicals, pharmaceutical components and products, dairy products, and food products. Such powder handling devices generally comprise at least a moving part and a non-moving part, so that the moving part is moving relative to the non-moving part during operation of the powder handling device, i.e. when the powder handling device is handling and/or processing a powder. Moving and non-moving parts of powder handling devices are typically connected via joints or bearings which allow the moving part to move relative to the non-moving part.

When processing powders, it is generally desired to maintain a low level of contamination as even a small level of contamination may render an entire batch of powder unsuitable for its purpose, such as human consumption, further manufacturing or the like.

Furthermore, there is a general desire to maintain a production over a certain period of time and reduce the downtime of a powder handling device to improve the powder handling efficiency and to maintain low operating costs of the powder handling device.

A source of contamination during manufacturing can be undesired mechanical contact between portions of the moving and non-moving parts of powder handling devices, for instance as a scraping or sliding contact of surfaces occurring between the moving and non-moving part. Undesired mechanical contact may, for instance, arise from wear and tear of bearings or the like. Such contact is generally undesired as the moving and non-moving parts are often made from a solid material, such as a metal, which, if brought into such physical contact during operation, may cause chips or swarf to be generated and contaminate the powder to be processed.

Existing sensor systems have been developed aiming at detecting undesired mechanical contacts between moving and non-moving parts of powder handling devices. Such existing systems often rely on detecting an electrical resistance between the moving and non-moving parts. In such systems, a low resistance between the two parts generally leads to a detection that there is a mechanical contact between the moving and non-moving parts. Typically, a mechanical contact detection is made when the resistance drops below a predetermined threshold.

However, due to the influence of, e.g., powders, cleaning agents, and noise in the system, a low resistance may occur, typically for short time durations, even when no mechanical contact takes place between the moving and non-moving parts. To reduce the number of false positives, i.e. determinations of mechanical contact when no mechanical contact was present, prior art sensor systems often introduce filtering or similar data processing, for instance so that a mechanical contact is detected only when the resistance has been low, e.g., below the threshold, for a certain period of time. This, however, introduces the risk of the system not detecting short-time mechanical contacts, i.e., generating false negatives.

### SUMMARY

It is an object of the present disclosure to overcome or alleviate at least some of the problems of this prior art and to provide a sensor system, a powder handling device, and a method, which overcomes or alleviates at least some of the problems of the prior art.

According to a first aspect of the disclosure, there is provided a sensor system for detecting a mechanical contact between a moving part and a non-moving part of a powder handling device, such as a rotary valve. The sensor system comprises an electrical signal source configured to provide a first electric signal, the first electric signal comprising a periodic signal component, which is periodic with a predetermined period. The sensor system further comprises a first electric component having a first electric impedance. The electrical signal source and the first electric component are configured to be electrically connected to the powder handling device so that the first electric component and the powder handling device are connected in series to the electrical signal source. The sensor system further comprises a first voltage and/or current sensor configured to, when the sensor system is connected to the powder handling device, output a first sensor signal indicative of a voltage and/or current of the first electric signal. The sensor system further comprises a second voltage and/or current sensor configured to, when the sensor system is connected to the powder handling device, output a second sensor signal indicative of a voltage across the powder handling device and/or a current through the powder handling device. The sensor system comprises a processing unit configured to receive the first and second sensor signals and determine a phase difference between the respective voltage of the first electric signal and the voltage across the powder handling device and/or between the respective current of the first electric signal and the current through the powder handling device. The processing unit is further configured to in response to a determination that the phase difference is below a predetermined threshold, output an output signal indicative of a mechanical contact between the moving part and the non-moving part of the powder handling device.

It has been realised that by relying on phase difference detection, a robust detection may be provided as the phase difference between the voltages and/or currents of the first and second signals generally decreases significantly during an undesired mechanical contact during operation compared to during normal operation. In some cases, the mechanical contact results in a near short-circuiting between the moving and non-moving part and the phase difference decreases to be in the range of approximately 0°. Furthermore, when the powder handling device is undergoing cleaning, such as cleaning-in-place, a cleaning fluid, for instance a cleaning liquid, is often applied to the powder handling device. Due to the capacitance of this fluid or liquid, however, there remains a phase difference during cleaning as long as there is no mechanical contact between the moving and non-moving part. Correspondingly, the sensor system according to the present disclosure similarly allows for a reliant and robust detection of mechanical contact between the moving and non-moving parts during cleaning of the powder handling device.

By providing a first and second voltage and/or current sensor to obtain the first sensor signal indicative of a voltage and/or current of the first electric signal and the second sensor signal indicative of a voltage across the powder handling device and/or the current through the powder handling device, respectively, a simple and robust determination of the phase difference may be allowed for. For instance, by determining, based on the sensor signals, a phase difference of the voltage signals, a simple, non-intrusive, and yet robust determination of the phase difference may be allowed for. Furthermore, each of the signals may be sampled by the sensors and further signal processed subsequently, e.g., to reduce potential signal noise, perform signal analysis or the like, potentially without interfering with the sensors and/or signals.

Throughout this text, it will be appreciated that the mechanical contact between the moving and non-moving parts refers to a mechanical or physical contact between the two parts during operation of the powder handling device. For instance, a such mechanical contact may be a mechanical contact between a section of the moving part and a section of the non-moving-parts, which sections are configured or arranged to come into contact with powder during operation of the powder handling device. Correspondingly, a mechanical contact in this context may be understood as an undesired mechanical contact, which does not include any operationally intended contact via bearings or the like.

A mechanical contact in this context may thus be a galvanic contact and/or an electrically conducting mechanical contact. For instance, the mechanical contact may be a mechanical contact incurring a short circuiting between rotor and stator.

Throughout this text, the terms capacitance, inductance, impedance, and resistance refer to electrical capacitance, electrical inductance, electrical impedance, and electrical resistance, respectively.

Throughout this text, it will furthermore be appreciated that the terms “electric impedance” and “electrical impedance” may be used interchangeably, however referring to the electrical impedance of the specific component(s). Similarly, an “electric” and “electrical” component and “electric” and “electrical” signal may be used interchangeably to denote the same component and signal, respectively.

By the first electric signal comprising a periodic signal component, which is periodic with a predetermined period, it will be appreciated that the predetermined period is different from infinite. Correspondingly, the periodic signal component has a frequency different from 0 Hz. As will be well-understood within the field of signal processing, an amplitude of the signal component, such as a voltage amplitude or a current amplitude, is periodic with the predetermined period.

The predetermined period may remain the same for all periods of the signal or may be altered during a duration of the signal. The periodic component may be or may comprise any periodic signal or waveform, such as a sine wave, a square wave, a triangular wave, sawtooth waveform, or any combination or superimposition thereof. For instance, the periodic component may be or result in a pulse-width modulated (PWM) signal, a sine signal, or the like.

The voltage across and/or current through the powder handling device may, during normal operation, have a periodic component identical to the periodic component of the first electric signal, however having a different phase, i.e. phase shifted or time shifted relative to the periodic component of the first electric signal. In some examples, a fundamental frequency of the periodic component of the voltage across and/or current through the powder handling device may, during normal operation, be the same as a fundamental frequency of the periodic component of the first electric signal. A periodic component of the voltage across and/or current through the powder handling device may have a same or different amplitude as the periodic component of the first electric signal.

The voltage across and/or current through the powder handling device may alternatively or additionally be denoted a second electric signal.

The powder handling device may be any powder handling device comprising a moving and a non-moving part. The moving part may be a part of the powder handling device configured to, during an intended operation of the powder handling device, move relative to the non-moving part. In some embodiments, the powder handling device is a rotary valve, comprising, as moving part, a rotor and, as non-moving part, a stator or a housing.

The powder handling device may be a rotating powder handling device, such as a rotary valve. The moving part may be a rotating part and the non-moving part may be a non-rotating part.

In some embodiments, the moving and non-moving parts may be electrically conductive and/or comprise an electrically conductive material, such as a metal, e.g., steel, aluminium, or various alloys.

The powder handling device may, in some embodiments, have a complex electrical impedance, potentially comprising a real part, such as a non-zero resistance, and a complex part, such as a non-zero reactance. The complex electrical impedance of the powder handling device may comprise a capacitive impedance and a resistive impedance and/or may correspond to an impedance of a resistor and a capacitor in parallel.

Throughout the present disclosure, it will be appreciated that a complex impedance refers to an impedance, Z, which can generally be set on the Cartesian form:

Z=R+jX
and the polar form:

Z=|Z|e^{j arg(Z)}
where R denotes resistance, X denotes reactance, and j denotes the imaginary unit.

It will be appreciated in the present disclosure that any description of impedance of components refers to impedance of the component during normal operation of the components and within the normal operation of the sensor system and the powder handling device as well as during any potential cleaning such as cleaning in place of the powder handling device. Notably, it will be appreciated that any impedance, and thereby resistance, reactance, capacitance, inductance or the like, of the components are when operated within the rated operating conditions including rated temperature, voltage, current, and/or frequency conditions. Moreover, it will be appreciated that any impedance, notably complex impedance, of any component disclosed herein refers to the impedance of the component at a frequency of the periodic signal component (e.g., the inverse of the predetermined period).

The first electric component may be configured to be arranged in between the powder handling device and the powder handling device when seen along a signal path of the electric signal. In some embodiments, the first electric component is configured to be connected, potentially directly connected, to the first signal source and/or to the powder handling device. In other embodiments, the sensor system further comprises one or more electrical components configured to be serially connected with the signal source and the first electrical component in between these and/or with the first electrical component and the powder handling device in between these.

The first and second voltage and/or current sensors may, potentially each, be any known voltage and/or current sensor, respectively. Examples of such sensors may be voltmeters, such as digital voltmeters, amperemeters, such as digital amperemeters, oscilloscopes, or the like. In some embodiments, the first and second voltage and/or current sensors may be implemented as one sensor or one sensor system.

In some embodiments, the first and second voltage and/or current sensors may, potentially each, be configured to continuously sense the respective voltage and/or current and output the respective signal based on the sensed voltage and/or current. Alternatively or additionally, the first and second voltage and/or current sensors may, potentially each, be configured to sample the respective voltage and/or current with a predetermined sampling rate and output the respective signal based on the sampled voltage and/or current.

The processing unit may comprise or be any known processing unit, such as a central processing unit (CPU), a microcontroller unit (MCU), a field-programmable gate array (FPGA), a digital signal processor (DSP), a programmable logic array (PLA), an application specific integrated circuit (ASIC), or the like or any combination thereof. In some embodiments, the processing unit may further comprise and/or be operationally connected to a non-transitory memory or a non-transitory computer-readable medium comprising instructions, which, when executed by the processing unit, causes the processing unit to receive the signals, determining the phase difference, and output the output signal. A such memory or non-transitory computer-readable medium may be or comprise a random access memory (RAM), read-only memory (ROM), a flash memory, a solid-state drive (SSD), or the like.

The processing unit may be configured to continuously comparing the determined phase difference to a predetermined threshold. Alternatively or additionally, the processing unit may be configured to compare the determined phase difference to a predetermined threshold at predetermined intervals and/or with a predetermined frequency.

The first electric impedance may be or may comprise a resistive impedance, at least in an intended operating range of the sensor system. In some embodiments, the first electric impedance may be a substantially resistive or resistive impedance, at least in an intended operating range. The first electric component may be a resistor or the like, such as a resistor, a fuse, or the like. The first electric component may alternatively or additionally be or comprise a diode, such as a Zener diode. In a such example, the diode may be selected or configured so that a current, at least in an intended operating range of the sensor system, is allowed to pass through the first component from the electrical signal source to the powder handling device. In this example, the diode may additionally be selected or configured so that any undesired voltages or currents, such as transients, electrostatic discharge (ESD), or the like do not pass from the electrical signal source to the powder handling device and/or are lead directly to a ground by the diode.

In some embodiments, the first electric component may be an intrinsic safety barrier as will be described in the following.

Where the first electric impedance is resistive, an easier determination of the phase difference may be provided as no phase difference is introduced merely by the first electrical component.

In other embodiments, the first electric component may be or comprise a capacitor, an inductor, or the like.

In some embodiments, the first electric component may comprise one or more components configured to be connected in parallel with the powder handling device or a serial connection of the powder handling device and another component. In an example, the first electric component comprises a Zener diode arranged to be connected in parallel with the powder handling device or a serial connection of the powder handling device and another component.

In some embodiments, a portion of the powder handling device, such as a non-moving part thereof, may be connected to a ground. Alternatively or additionally, the electrical signal source may be connected between the first component and a ground.

The output signal may be any signal, for instance to provide an indication to an operator of a contact or to be stored in a log. In some examples, the output signal may cause a visual indication to be provided on a display unit to an operator and/or may be sent to another electronic device wired or wirelessly.

In some embodiments, the sensor system further comprises a second electrical component having a second electrical impedance. The second electrical component may be configured to be electrically connected in parallel with the powder handling device.

Thereby, the second electrical component may, by its impedance, introduce a phase shift, so that an improved control of the phase difference during normal operation (i.e., when no mechanical contact is present) may be allowed for. This, in turn, allows for an improved robustness of the system and an improved detection of mechanical contact. For instance, the second electrical component may have an impedance which introduces an additional phase difference so that the difference between the phase difference during normal operation and the threshold is increased, thereby improving robustness.

Furthermore, by the second electrical component being configured to be electrically connected in parallel with the powder handling device, the voltage across the second electrical component will be substantially the same as the voltage across the powder handling device, thereby allowing for an easy voltage measurement. For instance, the second electrical component may comprise measurement points or connection interfaces suitable or adapted for connection to a second voltage sensor. In other examples, the second voltage sensor may be wired connected, such as hardwired, to the second electrical component.

The second electrical component may be or may comprise a single component or a plurality of components, such as passive components, e.g., resistors, capacitors, inductors, or semiconductors, e.g., diodes, integrated circuits, or the like.

The second electrical impedance may be different from the first electrical impedance.

The second electrical component may, in some embodiments, be configured and/or connected to provide a combined impedance of the second electrical component and the powder handling device, and optionally the first electrical component, wherein the combined impedance has an argument larger than an argument of the impedance of the powder handling device or, optionally, than an argument of an impedance of the combination of the first electrical component and the powder handling device.

The second electrical component may alternatively or additionally fulfil the following criteria, when the second electrical component is connected in series with the powder handling device: arg(Z_{phd}+Z₂)>arg(Z_{phd}), where Z_{phd} refers to the impedance of the powder handling device and Z₂ refers to the impedance of the second electrical component. Alternatively or additionally, the second electrical component may fulfil the following criteria when connected in series with the first electrical component and the powder handling device: arg(Z_{phd}+Z₁+Z₂)>arg(Z_{phd}+Z₁), where Z₁ refers to the impedance of the first electric component.

Similarly, where the second electrical component is connected in parallel to the powder handling device, the second electrical component may fulfil the following criteria:

$$arg ( \frac{1}{\frac{1}{{Z}_{phd} + \frac{1}{{Z}_{2}}}} ) > arg ( {Z}_{phd} ) and / or$$

$$arg ( \frac{1}{\frac{1}{{Z}_{phd} + {Z}_{1}} + \frac{1}{{Z}_{2}}} ) > arg ( {Z}_{phd} + {Z}_{1} ) .$$

In some embodiments, the second electrical component may be configured and/or arranged to introduce a phase, such as a phase shift, an additional phase shift, a phase difference, and/or an additional phase difference, between the first electric signal and the voltage across and/or current through the powder handling device. The second electrical component may be configured and/or arranged to introduce the phase between the voltage of the first electric signal and the voltage across the powder handling device and/or between the current of the first electric signal and the current through the powder handling device. The second electrical component may be configured and/or arranged to introduce the phase at least during normal or intended operation, namely when there is no mechanical contact between rotator and stator, of the powder handling device.

The second electrical component may alternatively or additionally be configured to and/or arranged to introduce an increased or further phase difference between the first electric signal and the voltage across and/or current through the powder handling device. The increased or further phase difference may be relative to the phase difference provided by the powder handling device itself, such as by an impedance of the powder handling device. The second electrical component may be configured to and/or arranged to introduce the increased or further phase difference during normal or intended operation, namely when there is no mechanical contact between rotator and stator, of the powder handling device.

In some embodiments, the second electrical impedance is a complex impedance.

The second electrical impedance may have a non-zero reactance, i.e. X₂≠0, and/or the argument of the second electrical impedance may be non-zero, i.e. arg(Z₂)≠0.

The second electrical impedance may comprise a reactance and/or wherein the electrical component comprises a capacitor with a predetermined capacitance.

Thus, the second electrical component may allow for a detection based on phase difference and independent from voltage amplitude of a voltage across the powder handling device and/or independent from a current amplitude of a current through the powder handling device.

The capacitor may be an electrolytic or tantalum capacitor, potentially having a capacitance of at least 1 μF. Alternatively, the capacitor may be a ceramic capacitor or a film capacitor. In some embodiments, the second electrical component may comprise a plurality of capacitors, such as electrolytic capacitors, tantalum capacitors, film capacitors, ceramic capacitors, or any combination thereof, connected so that a total capacitance of the second electrical component is a predetermined capacitance, such as at least 1 μF. For instance, at least some of the plurality of capacitors may be connected in parallel.

In some embodiments, the second electrical component may have a capacitance, which is larger than a capacitance or equivalent capacitance of the powder handling device during normal operation, i.e., when no mechanical contact is present. It will be appreciated that normal operation refers to an operation, in which the powder handling device is processing powder. A capacitance or equivalent capacitance of the powder handling device during normal operation thus refers to the capacitance of the powder handling device, optionally including powder to be processed, but generally does not include any capacitance or equivalent capacitance introduced by a cleaning fluid, such as a cleaning liquid or the like, applied during a potential cleaning-in-place (CIP) process.

In some embodiments, the second electrical impedance additionally or alternatively comprises a resistance. Alternatively or additionally, the electrical component comprises a resistor with a predetermined resistance.

The resistor may be configured to be arranged in parallel with the powder handling device.

Thereby, an improved robustness of the system may be allowed for as the resistance and/or resistor may prevent or reduce the risk that an electrical potential is built up on the moving part of the powder handling device during operation by the resistance and/or resistor allowing for discharging a such electrical potential. Thereby, a risk of an ignition source appearing in the powder handling device is reduced, in turn improving the safety as well as the robustness of the sensor system.

In some embodiments, a resistor of the second electrical component may have a same resistance as the first electrical component, at least during normal operation of the powder handling device. Alternatively or additionally, a resistance of the second electrical impedance may be substantially the same or the same as a resistance of the first electrical impedance. Alternatively, the resistance of the first electrical impedance may be between 50% and 100%, such as between 60% and 100%, between 70% and 100%, between 80% and 100%, or between 90% and 100% of the resistance of the second electrical impedance. Alternatively, the resistance of the second electrical impedance may be between 50% and 100%, such as between 60% and 100%, between 70% and 100%, between 80% and 100%, or between 90% and 100% of the resistance of the first electrical impedance.

The resistance of the first and/or the second electrical component may be between 1Ω and 50Ω, such as between 2Ω and 40Ω, such as between 3Ω and 35Ω, such as between 5Ω and 30Ω, such as between 10Ω and 25Ω, such as between 15Ω and 25Ω. By resistance is herein understood a resistance of the respective components in a direction of the signal, namely from the signal generator through the first electric component and any potential intrinsic safety barrier where a such is provided, and through the second electric component. Where the sensor system further comprises an intrinsic safety barrier, any resistance thereof may be included in the impedance of the first electric component in the above, for instance so that a resistance of the serial connection of the first electrical component and the intrinsic safety barrier is between 1Ω and 50Ω. Where the first electrical component is or comprises an intrinsic safety barrier, the intrinsic safety barrier may similarly have a resistance between 1Ω and 50Ω as described above with respect to the first electrical component.

In some examples, the second electrical component may comprise a semiconductor, such as a transistor or a diode, arranged to provide the resistance at least during normal operation. As an example, the second electrical component comprises a diode or Zener diode may be configured to be arranged in parallel with the powder handling device.

Alternatively or additionally, the second electrical component may be or comprise a filter device, such as a filter device configured to introduce a phase shift at a frequency, for instance at a fundamental frequency, of the first electric signal. The filter device may, for instance, be configured to be arranged in series with the powder handling device.

In some embodiments, the sensor system comprises an intrinsic safety barrier.

Thereby, an increased safety and robustness of the system may be provided, as the intrinsic safety barrier may reduce the risk of excessive voltage and currents in the circuit, which may arise in a potential error condition of the sensor system.

By an intrinsic safety barrier may herein be understood an electric component or combination of electrical components configured prevent transfer of large amounts of energy, i.e. energy amounts outside of a normal operating range, between the signal source and the powder handling device. Consequently, the intrinsic safety barrier may alternatively be denoted a safety barrier, a barrier, a limiting component, such as a voltage and/or current limiting component, or a safety isolator.

The intrinsic safety barrier may be configured to clamp, limit, or maintain a current and/or voltage to be below a predetermined safety threshold and/or within a predetermined safety range. For instance, an intrinsic safety barrier may be configured to limit a voltage across the powder handling device and/or a current flowing between the signal source and the powder handling device. Alternatively or additionally, the intrinsic safety barrier may be configured to limit the voltage and/or current of a signal, such as the voltage across the powder handling device and/or the current through the powder handling device, to remain below a predetermined amplitude.

The intrinsic safety barrier may be included in the first electrical component or comprised by the first electrical component. In some examples, the intrinsic safety barrier may comprise a number of passive electric components, such as resistors, capacitors, inductors, and/or a number of semiconductors, such as diodes, transistors, operational amplifiers, integrated circuits, or the like.

The intrinsic safety barrier may have an impedance when seen along the signal path from the signal generator to the powder handling device. The impedance may a real impedance, such as a resistance, at least during normal operation and/or a cleaning operation of the powder handling device. Where the intrinsic safety barrier is comprised by or included in the first electrical component, the first electrical impedance may comprise the impedance of the intrinsic safety barrier.

In some embodiments, the intrinsic safety barrier may be the first electrical component. Where the intrinsic safety barrier is the first electrical component, the first electric impedance may be the impedance of the intrinsic safety barrier.

The impedance, such as the resistance, of the intrinsic safety barrier may be identical or similar to the first electrical impedance as described with respect to the first electrical component in the preceding when seen along a signal direction from the electrical signal source to the powder handling device.

In some examples, the intrinsic safety barrier is configured to be electrically connected, when the sensor system is connected to the powder handling device, in between the electrical signal source and the powder handling device, such as between the first component and the electrical signal source or between the first component and the powder handling device.

Thereby the influence of the intrinsic safety barrier on the voltage and/or current measured by the first and second voltage and/or current sensors may be reduced, thereby allowing for an increased accuracy of the sensor system.

Where the intrinsic safety barrier is comprised by or included in the first electrical component, the intrinsic safety barrier may be configured to be connected in series with the electrical signal source and the powder handling device, such as in between these, optionally in series with one or more further components of the first electrical component. Thereby, a signal path of the first electrical signal may be from the signal generator through the first electrical component including at least part of the intrinsic safety barrier to the powder handling device.

Where the first electrical component is the intrinsic safety barrier, the intrinsic safety barrier may be configured to be connected as described with respect to the first electrical component, optionally so that a signal path of the first electrical signal is from the signal generator through at least part of the intrinsic safety barrier to the powder handling device.

In some embodiments, the sensor system comprises a measurement intrinsic safety barrier. The measurement intrinsic safety barrier may be configured to be electrically connected to a first terminal of the second voltage and/or current sensor.

Thereby, an increased safety and robustness of the system may be provided, as the intrinsic safety barrier may reduce the risk of that excessive voltage and/or currents are provided to the second voltage and/or current sensor, which again reduces the risk of overloading and, potentially, excessively wearing or breaking the second voltage and/or current sensor.

In some embodiments, the intrinsic safety barrier is the measurement intrinsic safety barrier. In some embodiments, the sensor system comprises the intrinsic safety barrier, e.g., a first intrinsic safety barrier, and further comprises the measurement intrinsic safety barrier.

It will be appreciated that any feature or function described herein with respect to the intrinsic safety barrier may equally apply to the measurement intrinsic safety barrier.

The intrinsic safety barrier and/or the measurement intrinsic safety barrier, where the sensor system comprises this, may comprise a Zener diode.

The intrinsic safety barrier and/or any measurement intrinsic safety barrier may each comprise a semiconductor, such as a diode or Zener diode, and, optionally, one or more passive components.

In some embodiments, the intrinsic safety barrier and/or the measurement intrinsic safety barrier, where the sensor system comprises this, is a Zener barrier. Zener barriers are as such a common type of known intrinsic safety barriers.

The (first) intrinsic safety barrier may comprise a first Zener diode and an oppositely directed second Zener diode, a fuse, and a resistor. The fuse and the resistor may be configured to be serially connected in between the first electrical component and the powder handling device, optionally so that the first electrical component configured to be serially connected via the fuse and the resistor to the powder handling device. The first and second Zener diodes may be connected between a ground and a node between the fuse and the resistor.

The measurement intrinsic safety barrier may comprise a first Zener diode and an oppositely directed second Zener diode, a fuse, and a resistor. The fuse and the resistor may be configured to be serially connected in between a measurement point of the powder handling device, optionally so that the measurement point is configured to be serially connected via the fuse and the resistor to the second voltage and/or current sensor. The first and second Zener diodes may be connected between a ground and a node between the fuse and the resistor.

In some embodiments, the sensor system comprises a filter, wherein a transfer function of the filter is selected so that at least a predetermined frequency of the input signal and/or the voltage across and/or current through the powder handling device is in a passband of the filter.

Thereby, potential other components in the signal, such as undesired noise, undesired frequency components, or the like may be filtered out. This may, again, allow for an improved signal-to-noise ratio (SNR) of the periodic signal component of the voltage and/or current of the first electrical signal and/or the corresponding potentially phase-shifted voltage across and/or current through the powder handling device. Thereby, the phase difference may be determined more reliably and, thus, an improved accuracy and robustness of the system may be provided.

By a passband of the filter will herein be understood any band of frequencies of the filter, in which a signal of the frequency may be allowed to pass. Correspondingly, a passband will be understood to be a frequency range different from a frequency range of a stopband of the filter.

By the transfer function of the filter being selected as mentioned herein, it will be appreciated that the filter may be configured to have a passband, within which the predetermined frequency of the input signal and/or the voltage across and/or current through the powder handling device. Alternatively or additionally, the filter may be designed to have a passband, within which the predetermined frequency of the input signal and/or the voltage across and/or current through the powder handling device

The predetermined frequency of the input signal may be the inverse of the predetermined period. Alternatively or additionally, the predetermined frequency may be another frequency present in the signal.

It will be appreciated that in some embodiments, the predetermined frequency may be a fundamental frequency of the periodic component of the first electric signal and/or a fundamental frequency of a periodic component of the voltage across and/or current through the powder handling device.

In some embodiments, the filter is arranged and connected in between a measurement terminal of the first voltage and/or current sensor and the first electric signal source, potentially so that the first voltage and/or current sensor receives a filtered first electrical signal. Alternatively or additionally, the filter may be arranged and connected in between a measurement terminal of the second voltage and/or current sensor and the powder handling device so that the second voltage and/or current sensor receives a filtered voltage across and/or current through the powder handling device.

In some embodiments, the filter is electrically connected between a first terminal of the second voltage and/or current sensor and a measurement point of the powder handling device.

Thereby, an increased reliability of the measurement may be provided as undesired signal components, such as noise or the like, may be filtered out prior to measurement without influencing the signal path of the system, i.e. the signal from the electrical signal source through the powder handling device.

The measurement point of the powder handling device may be any point, to which the second voltage and/or current sensor is connected. In some embodiments, the measurement point may be a measurement terminal or the like of the powder handling device. The measurement point may be different from a ground point or a grounded point of the powder handling device.

In some embodiments, the sensor system comprises a second filter, wherein a transfer function of the second filter is selected so that at least a predetermined frequency of the input signal and/or the voltage across and/or current through the powder handling device is in a passband of the second filter, and wherein the filter is electrically connected between a first terminal of the first voltage and/or current sensor and a measurement point of the electrical signal source.

It will be appreciated that the filter may be denoted a “first filter” or an “output filter”. Alternatively or additionally, the second filter may be denoted as an “input filter”. Furthermore, in some embodiments, the sensor system may comprise a such input filter without comprising an output filter or vice versa. In other embodiments, the sensor system may comprise both an input and an output filter. Consequently, it will be appreciated that the sensor system may comprise the (first) filter or the second filter or both the (first) filter and the second filter.

By providing the second filter, a more reliable detection and/or sampling of the first electric signal may be provided.

The transfer function of the (first) filter and the second filter may be identical and/or have passbands with overlapping frequencies or overlapping frequency ranges. The (first) filter and/or the second filter may alternatively or additionally be identical.

The (first) filter and/or the second filter may be implemented as time-discrete or digital filters, such as finite impulse response (FIR) digital filters, or analogue filters, such as an RC filter, an RL filter, a LC filter, or the like. In some embodiments, the (first) filter and/or the second filter may, potentially each, comprise one or more passive components, such as resistors, capacitors, and inductors, and/or one or more semiconductors, such as operational amplifiers, integrated circuits, transistors, or the like.

In some embodiments, the filter is or comprises one or more of a low-pass filter, a high-pass filter, and a band-pass filter. In some embodiments, the second filter alternatively or additionally is or comprises one or more of a low-pass filter, a high-pass filter, and a band-pass filter.

A second aspect of the disclosure relates to a powder handling device comprising a sensor system according to the first aspect.

The powder handling device according to the second aspect may comprise any features described in the preceding with respect to the first aspect and may provide any advantage described in the preceding with respect to the sensor system according to the first aspect.

A third aspect of the disclosure relates to a method for detecting a mechanical contact between a moving part and a non-moving part of a powder handling device, such as a rotary valve. The method comprises:
electrically connecting an electrical signal source, the powder handling device, and a first electric component having a first electric impedance so that the first electric component and the powder handling device are connected in series to the electrical signal source;
providing, by the electrical signal source, a first electric signal, the first electric signal comprising a periodic signal component, which is periodic with a predetermined period;
generating, by a first voltage and/or current sensor, a first sensor signal indicative of a voltage and/or current of the first electric signal;
generating, by a second voltage and/or current sensor, a second sensor signal indicative of a voltage across the powder handling device and/or a current through the powder handling device;
receiving, by a processing unit, the first and second sensor signals and determining a phase difference between the respective voltage of the first electric signal and the voltage across the powder handling device and/or between the respective current of the first electric signal and the current through the powder handling device; and
in response to a determination by the processing unit that the phase difference is below a predetermined threshold, output an output signal indicative of a mechanical contact between the moving part and the non-moving part of the powder handling device.

The method according to the third aspect may comprise any features described in the preceding with respect to the first aspect and may provide any advantage described in the preceding with respect to the sensor system according to the first aspect.

The electrical signal source, the first voltage and/or current sensor, the second voltage and/or current sensor, and the processing unit may be of a sensor system according to the first aspect. Alternatively or additionally, the method may comprise the step of providing a sensor system according to the first aspect of the disclosure.

Generating the first sensor signal may comprise determining, by the first voltage and/or current sensor, a voltage of the first electric signal and/or a current of the first electric signal and generating, based on the determined voltage and/or current, the first sensor signal.

Generating the second sensor signal may comprise determining, by the second voltage and/or current sensor, a voltage across and/or a current through the powder handling device and generating, based on the determined voltage and/or current, the second sensor signal.

It will be appreciated that the electrical signal source, the first voltage and/or current sensor, the second voltage and/or current sensor, the processing unit, and the powder handling device may comprise any feature or have any advantage as described with respect to the sensor system according to the first aspect of the disclosure.

The different aspects of the present disclosure can be implemented in different ways including as a sensor system for detecting a mechanical contact between a moving part and a non-moving part of a powder handling device, a powder handling device comprising the sensor system, and a method for detecting a mechanical contact between a moving part and a non-moving part of a powder handling device described above and in the following, each yielding one or more of the benefits and advantages described in connection with at least one of the aspects described above, and each having one or more preferred embodiments corresponding to the embodiments described in connection with at least one of the aspects described above and/or disclosed in the dependent claims. Furthermore, it will be appreciated that embodiments described in connection with one of the aspects described herein may equally be applied to the other aspects.

### BRIEF DESCRIPTION OF DRAWINGS

In the following description embodiments of the disclosure will be described with reference to the schematic drawings, in which

FIGS. 1a and 1b are schematic cross-sectional views of two different powder handling devices, more specifically rotary valves;

FIGS. 2a and 2b are schematic cross-sectional views of a powder handling device provided with a prior art sensor system in two different states;

FIG. 3 is a graph showing amplitude versus time for an alternating electrical input signal and an alternating electrical output signal;

FIG. 4 shows an overall schematic circuit diagram of a sensor system according to an embodiment of the present disclosure;

FIGS. 5a and 5b shows an overall schematic circuit diagram of a sensor system according to another embodiment of the present disclosure;

FIG. 6 shows an overall schematic circuit diagram of a sensor system according to an embodiment of the present disclosure; and

FIG. 7 shows an overall schematic circuit diagram of a sensor system according to an embodiment of the present disclosure;

### DETAILED DESCRIPTION

The present disclosure will now be described more fully hereinafter with reference to the accompanying drawings, in which embodiments of the disclosure are shown. This disclosure may, however, be embodied in many different forms and should not be construed as limited to the embodiments set forth herein; rather, these embodiments are provided for thoroughness and completeness.

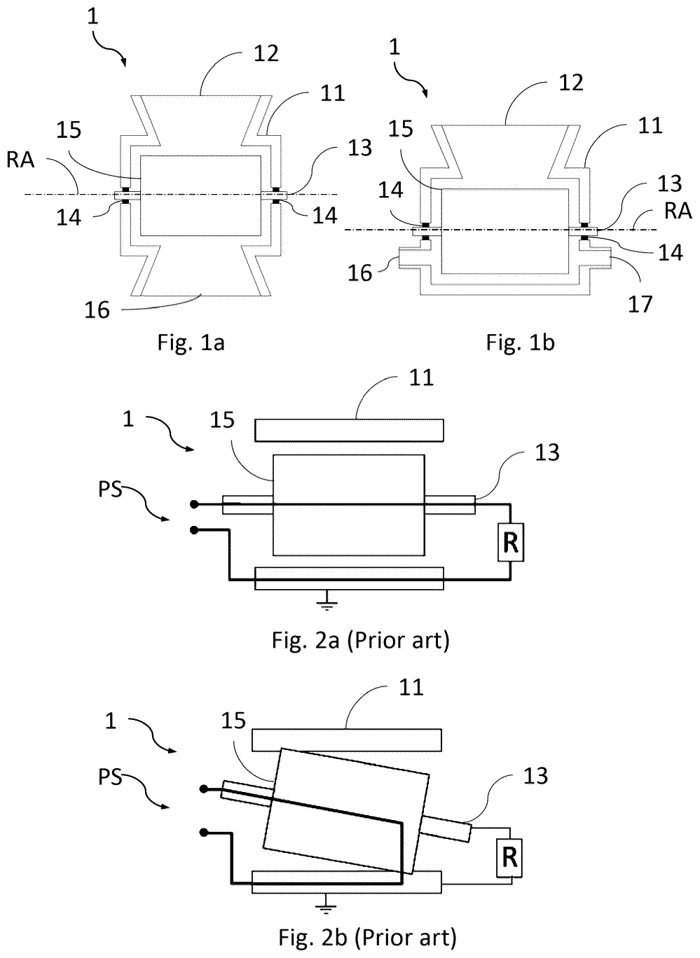

Referring initially to FIGS. 1a and 1b, two different powder handling devices in the shape of rotary valves 1 are shown. Both rotary valves 1 comprise a housing 11. The housing 11 is typically made of stainless steel, but other suitable materials are conceivable. An inlet 12 is formed in a section of the housing 11, the inlet 12 being for receiving a powder stream into the interior of the housing 11. The inlet 12 may as shown take the form of a funnel 12. The inlet 12 may also be an opening in the housing 11 connected to a hopper or similar. In this embodiment, the inlet 12 is formed in a top section of the housing 11, thus allowing powder to fall into the housing 11. Within the housing 11 is placed a rotor. The rotor comprises a rotor shaft 13 defining an axial direction and a radial direction, the rotor further comprises a plurality of vanes 15 connected to the rotor shaft 13 and extending radially from the rotor shaft 13. The rotor shaft 13 and the plurality of vanes 15 are configured to rotate around a rotation axis RA parallel with the axial direction within the housing 11 without contacting the housing 11. The vanes 15 are normally arranged so a gap is formed between the housing 11 and the vanes 15, the gap is preferably so small it hinders passage of powder. The vanes 15 defines compartments for receiving powder from the inlet 12. The vanes 15 and the rotor shaft 13 are set to rotate at a speed, low enough to ensure a spark is not created if the vanes 15 come into contact with the housing 11. The rotor is here connected to the housing via an insulating connection 14. The insulating connection 14 may be insulating bearings or an insulating sleeve. In the shown embodiment the rotor shaft 13 is connected to the housing 11 via the insulating connection 14. An outlet 16 is formed in a section of the housing 11. In the embodiment shown, the outlet 16 is formed in a bottom section of the housing 11, thus allowing powder to exit the housing 11 by falling through the housing. In the rotary valve shown FIG. 1a the outlet 16 is formed directly opposite of the inlet 11, where both the inlet 11 and the outlet 16 allow passage of powder in a direction perpendicular to the rotation axis RA. However, FIG. 1b shows a different embodiment where the outlet 16 is not formed directly opposite of the inlet 11. In FIG. 1b the inlet 11 allows passage of powder in a direction perpendicular to the rotation axes RA and the outlet 16 allows passage of powder in a direction parallel to the rotation axis RA. Furthermore, an additional inlet 17 is formed in the housing 11. The additional inlet 17 allows for a stream of air being introduced into the housing. The stream of air is intended for being for blowing powder into the outlet 16.

Referring to FIGS. 2a and 2b, schematic cross-sectional views of a powder handling device 1 provided with a prior art sensor system 2′ in two different states are shown. In a first state, shown FIG. 2a, the powder handling device is in normal operation. In the first state the prior art sensor system 2′ provides a direct current which passes through the rotor and the housing 11 of the powder handling device 1 in addition to a resistance R. In a second state, shown FIG. 2b, the powder handling device 1 is in an abnormal state where the vanes 15 of the rotor contacts the housing 11. In the second state the prior art sensor system 2′ provides a direct current which passes through the rotor and the housing 11 of the powder handling device 1, however the resistance R is short circuited because of the contact between the vanes 15 and the housing 11. Thus, by monitoring the direct current in the prior art sensor system 2′ it is possible to determine whether the resistance R is being short circuited. However, the direct current supplied is of a small magnitude to avoid charging any components which in return may lead to sparks being produced, which may be disastrous when handling powders. The small magnitude of the direct current leads to a low SNR, which may lead to false alarms or real alarms being filtered away.

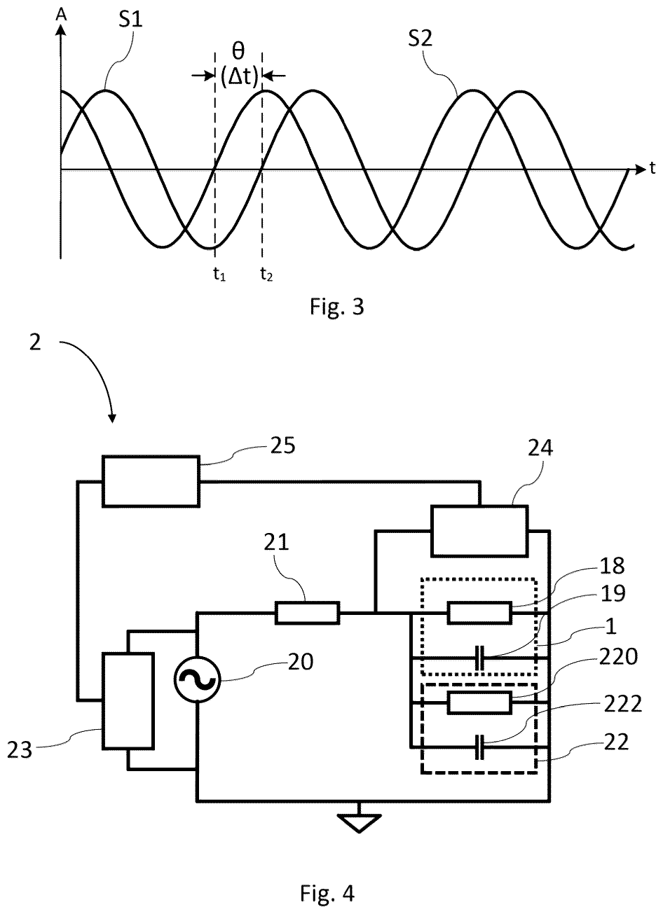

Referring to FIG. 3, a graph showing amplitude versus time for a first electric signal S1, such as a voltage of the periodic component of the first electric signal, and a second electric signal S2, such as a periodic component of a voltage across a powder handling device connected to a sensor system according to the present disclosure, is shown. In FIG. 3, the signals S1, S2 are illustrated as sinusoid signals having a same frequency. As shown in FIG. 3, a phase difference θ, also illustrated as a time difference Δt, is present between the signals S1, S2.

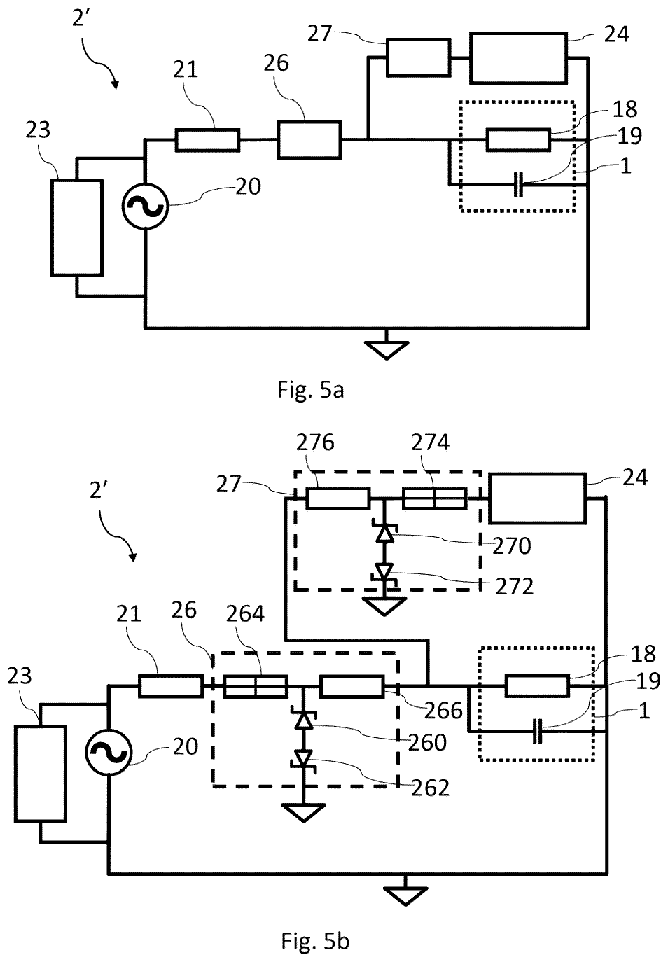

FIG. 4 shows an overall schematic of a sensor system 2 according to an example. The sensor system 2 is suitable for and configured to detect a mechanical contact between a moving part and a non-moving part of a powder handling device 1, such as a rotary valve.

In FIG. 4, the sensor system is illustrated in a connected state, in which it is connected to the powder handling device 1, which is, in turn, illustrated by a circuit equivalent corresponding to its impedance. The circuit equivalent consists of resistor 18 and capacitor 19. It will, however, be appreciated that this may be an impedance model, such as a simplified impedance model, or a simplified equivalent and that, in other embodiments, the powder handling device 1 and/or the impedance thereof may be illustrated differently, i.e., by comprising additional or different components.

The sensor system 2 comprises an electrical signal source 20 configured provide a first electric signal, the first electric signal comprising a periodic signal component, which is periodic with a predetermined period. An example of a such periodic signal component may be S1 as illustrated in FIG. 3. It will, however, be appreciated that any other periodic signal component may alternatively or additionally be comprised by the first signal.

The sensor system 2 further comprises a first electric component 21 having a first electric impedance. The electrical signal source 20 and the first electric component 21 are configured to be electrically connected to the powder handling device 1 so that the first electric component and the powder handling device are connected in series to the electrical signal source as illustrated in FIG. 4.

The sensor system 2 further comprises a first voltage sensor 23 configured to, when the sensor system 2 is connected to the powder handling device 1, output a first sensor signal indicative of a voltage of the first electric signal.

The sensor system 2 further comprises a second voltage sensor 24 configured to, when the sensor system 2 is connected to the powder handling device 1, output a second sensor signal indicative of a voltage across the powder handling device 1.

The sensor system 2 comprises a processing unit 25 configured to receive the first and second sensor signals and determine a phase difference between the respective voltage of the first electric signal and the voltage across the powder handling device 1 and/or between the respective current of the first electric signal and the current through the powder handling device. The processing unit is further configured to in response to a determination that the phase difference is below a predetermined threshold, output an output signal indicative of a mechanical contact between the moving part and the non-moving part of the powder handling device.

While the first 23 and second sensors 24 are illustrated as voltage sensors in FIG. 4, it will be appreciated that these might equally be implemented as current sensors configured to determine a current of the first signal and a current through the powder handling device, respectively. In a such example, the processing unit 25 is configured to determine a phase difference between the respective current of the first electric signal and the current through the powder handling device 1.

The first electric impedance is a resistive impedance. Correspondingly, the first electric component 21 is a resistor as shown in FIG. 4. In other embodiments, the first electric component 21 may be a different component or part of another component, such as an intrinsic safety barrier.

A portion of the powder handling device, such as a non-moving part thereof, may be connected to a ground as illustrated in FIG. 4. Furthermore, the electrical signal source 20 is connected between the first electric component 21 and the ground. While illustrated in FIG. 4 as a signal ground, the ground connection may alternatively or additionally be a chassis ground or an earth ground.

In the embodiment shown in FIG. 4, the sensor system 2 further comprises a second electrical component 22 having a second electrical impedance. The second electrical component 22 is configured to be electrically connected in parallel with the powder handling device 1 as shown in FIG. 4 in the connected state.

The second electrical impedance is a complex impedance with a non-zero reactance, i.e. X₂≠0, and the argument of the second electrical impedance is non-zero, i.e. arg(Z₂)≠0.

The second electrical impedance comprises a reactance and the electrical component 22 comprises, as shown in FIG. 4, a capacitor 222 with a predetermined capacitance.

The second electrical impedance additionally comprises a resistance as shown by the second electrical component 22 comprising a resistor 220 with a predetermined resistance.

The resistor 220 is, in the connected state shown in FIG. 4, arranged in parallel with the powder handling device 1.

FIGS. 5a and 5b shows an overall schematic circuit diagram of a sensor system 2′ according to another example.

The sensor system 2′ comprises, similarly to the sensor system 2, electrical signal generator 20, first electric component 21, first voltage sensor 23, second voltage sensor 24, and processing unit 25 (not illustrated in FIGS. 5a and 5b for simplicity).

The sensor system 2′ differs from the sensor system 2 shown in FIG. 4 in that the sensor system 2′ comprises an intrinsic safety barrier, i.e. first intrinsic safety barrier 26, and a measurement intrinsic barrier 27. While the embodiment of the sensor system 2′ shown in FIGS. 5a and 5b does not comprise a second electrical component 22, it will be appreciated that in other embodiments, the sensor system 2′ may comprise a second electrical component arranged in parallel with the powder handling device 1 and as described with respect to FIG. 4.

The first intrinsic safety barrier 26 and the measurement intrinsic safety barrier 27 are each configured to limit a current and voltage to be below a predetermined safety threshold and/or within a predetermined safety range. The first intrinsic safety barrier 26 is configured to limit a voltage across the powder handling device 1 and a current flowing between the electrical signal source 20 and the powder handling device 1.

The first intrinsic safety barrier 26 and the measurement intrinsic safety barrier 27 are both Zener barriers as shown in higher schematic detail in FIG. 5b. The first intrinsic safety barrier 26 comprises a first Zener diode 260 and an oppositely directed second Zener diode 262, a fuse 264, and a resistor 266. The fuse 264 and the resistor 266 are serially connected in between the first electrical component 21 and the powder handling device 1. The first 260 and second Zener diodes 262 are connected between ground and the node between the fuse 264 and the resistor 266.

Similarly, the measurement intrinsic safety barrier 27 comprises a first Zener diode 270 and an oppositely directed second Zener diode 272, a fuse 274, and a resistor 276. The fuse 274 and the resistor 276 are serially connected in between a measurement point of the powder handling device 1 and a measurement terminal of the second voltage sensor 24. The first 270 and second Zener diodes 272 are connected between ground and the node between the fuse 274 and the resistor 276.

The first intrinsic safety barrier 26 has an impedance when seen along the signal path from the signal generator to the powder handling device. The impedance is a real impedance, namely a resistance.

In other embodiments, the first intrinsic safety barrier 26 may be comprised by or included in the first electrical component, and/or the first electrical impedance may comprise the impedance of the (first) intrinsic safety barrier.

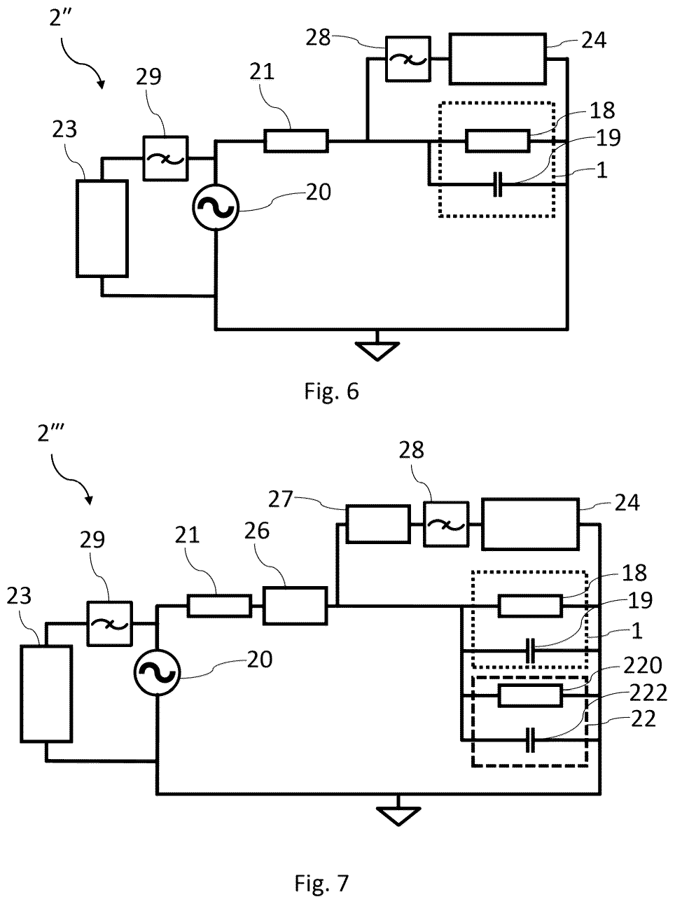

FIG. 6 shows an overall schematic circuit diagram of a sensor system 2″ according to another example.

The sensor system 2″ comprises, similarly to the sensor systems 2, 2′ an electrical signal generator 20, first electric component 21, first voltage sensor 23, second voltage sensor 24, and processing unit 25 (not illustrated in FIG. 6 for simplicity).

The sensor system 2″ differs from the sensor system 2 shown in FIG. 4 and sensor system 2′ shown in FIGS. 5a and 5b in that the sensor system 2″ comprises a filter, namely first filter 28, and a second filter 29. While the embodiment of the sensor system 2″ shown in FIG. 6 does not comprise a second electrical component 22, it will be appreciated that in other embodiments, the sensor system 2″ may comprise a second electrical component arranged in parallel with the powder handling device 1 and as described with respect to FIG. 4. Similarly, the sensor system 2″ may in other embodiments, comprise a first intrinsic safety barrier 26 and/or a second intrinsic safety barrier 27 as described with respect to sensor system 2′.

A transfer function of the first filter 28 is selected so that at least a predetermined frequency of the voltage across the powder handling device 1 is in a passband of the first filter 28. For instance, where the first electric signal or at least the periodic component is S1, the voltage across the powder handling device 1 may be the signal S2 or have a periodic component corresponding to signal S2, and the transfer function of the first filter 28 is then selected so that the frequency of S2 is in the passband of the first filter 28.

The first filter 28 is electrically connected between a first terminal of the second voltage sensor 24 and a measurement point of the powder handling device 1. The measurement point is different from a ground point or a grounded point of the powder handling device 1.

The sensor system 2″ further comprises a second filter 29. A transfer function of the second filter 29 is selected so that at least a predetermined frequency of the input signal is in a passband of the second filter 29. The second filter 29 is electrically connected between a first terminal of the first voltage sensor 23 and a measurement point of the electrical signal source 20.

FIG. 7 shows an overall schematic circuit diagram of a sensor system 2″ according to another example.

The sensor system 2″ comprises, similarly to the sensor systems 2, 2′ an electrical signal generator 20, first electric component 21, first voltage sensor 23, second voltage sensor 24, and processing unit 25 (not illustrated in FIG. 6 for simplicity).

The sensor system 2″ further comprises the second electrical component 22 having a second electrical impedance, comprising resistor 220 and capacitor 222. The second electrical component 22 is configured to be electrically connected in parallel with the powder handling device 1.

The sensor system 2″ further comprises the first intrinsic safety barrier 26 and the measurement intrinsic safety barrier 27, each configured to limit a current and voltage to be below a predetermined safety threshold and/or within a predetermined safety range.

The sensor system 2″ further comprises the first filter 28 and the second filter 29. In the embodiment shown in FIG. 7, the first filter 28 is connected (serially) in between a measurement terminal of the second voltage sensor 24 and the second intrinsic safety barrier 27. In other examples, the second intrinsic safety barrier 27 may be connected (serially) in between a measurement terminal of the second voltage sensor 24 and the first filter 28, i.e., their position may be swapped in the schematic circuit diagram shown in FIG. 7.

Although some embodiments have been described and shown in detail, the present disclosure is not restricted to them, but may also be embodied in other ways within the scope of the subject matter defined in the following claims. In particular, it is to be understood that other embodiments may be utilised and structural and functional modifications may be made without departing from the scope of the present disclosure.

In device claims enumerating several means, several of these means can be embodied by one and the same item of hardware. The mere fact that certain measures are recited in mutually different dependent claims or described in different embodiments does not indicate that a combination of these measures cannot be used to advantage.

It should be emphasized that the term “comprises/comprising” when used in this specification is taken to specify the presence of stated features, integers, steps or components but does not preclude the presence or addition of one or more other features, integers, steps, components or groups thereof.

1. A sensor system for detecting a mechanical contact between a moving part and a non-moving part of a powder handling device, such as a rotary valve, wherein the sensor system comprises:
an electrical signal source configured to provide a first electric signal, the first electric signal comprising a periodic signal component, which is periodic with a predetermined period;
a first electric component having a first electric impedance,
wherein the electrical signal source and the first electric component are configured to be electrically connected to the powder handling device so that the first electric component and the powder handling device are connected in series to the electrical signal source,
the sensor system further comprising:
a first voltage and/or current sensor configured to, when the sensor system is connected to the powder handling device, output a first sensor signal indicative of a voltage and/or current of the first electric signal;
a second voltage and/or current sensor configured to, when the sensor system is connected to the powder handling device, output a second sensor signal indicative of a voltage across the powder handling device and/or a current through the powder handling device;
a processing unit configured to receive the first and second sensor signals and determine a phase difference between the respective voltage of the first electric signal and the voltage across the powder handling device and/or between the respective current of the first electric signal and the current through the powder handling device, the processing unit further being configured to:
in response to a determination that the phase difference is below a predetermined threshold, output an output signal indicative of a mechanical contact between the moving part and the non-moving part of the powder handling device.

2. The sensor system according to claim 1 further comprising a second electrical component having a second electrical impedance, wherein the second electrical component is configured to introduce a phase shift between the first electric signal and the voltage across and/or current through the powder handling device, respectively.

3. The sensor system according to claim 2, wherein the second electrical impedance is a complex impedance.

4. The sensor system according to claim 2, wherein the second electrical component being configured to be electrically connected in parallel with the powder handling device and wherein the second electrical impedance comprises a reactance and/or wherein the electrical component comprises a capacitor with a predetermined capacitance.

5. The sensor system according to claim 2, wherein the second electrical impedance comprises a resistance and/or wherein the electrical component comprises a resistor with a predetermined resistance.

6. The sensor system according to claim 1, wherein the sensor system comprises an intrinsic safety barrier.

7. The sensor system according to claim 6, wherein the intrinsic safety barrier is configured to be electrically connected, when the sensor system is connected to the powder handling device, in between the electrical signal source and the powder handling device, such as between the first component and the electrical signal source or between the first component and the powder handling device.

8. The sensor system according to claim 6, wherein the sensor system comprises a measurement intrinsic safety barrier, the measurement intrinsic safety barrier being configured to be electrically connected to a first terminal of the second voltage and/or current sensor.

9. The sensor system according to claim 8, wherein one or more of the intrinsic safety barrier or the measurement intrinsic safety barrier comprises a Zener diode.

10. The sensor system according to claim 1, wherein the sensor system comprises a filter, wherein a transfer function of the filter is selected so that at least a predetermined frequency of the input signal and/or the voltage across and/or current through the powder handling device is in a passband of the filter.

11. The sensor system according to claim 10, wherein the filter is electrically connected between a first terminal of the second voltage and/or current sensor and a measurement point of the powder handling device.

12. The sensor system according to claim 10, wherein the sensor system comprises a second filter, wherein a transfer function of the second filter is selected so that at least a predetermined frequency of the input signal and/or the voltage across and/or current through the powder handling device is in a passband of the second filter, and wherein the filter is electrically connected between a first terminal of the first voltage and/or current sensor and a measurement point of the electrical signal source.

13. The sensor system according to claim 12, wherein the filter comprises one or more of a low-pass filter, a high-pass filter, and a band-pass filter, and wherein the second filter comprises one or more of a low-pass filter, a high-pass filter, and a band-pass filter.

14. A powder handling device comprising a sensor system according to claim 1.

15. A method for detecting a mechanical contact between a moving part and a non-moving part of a powder handling device, such as a rotary valve, the method comprising:
electrically connecting an electrical signal source, the powder handling device, and a first electric component having a first electric impedance so that the first electric component and the powder handling device are connected in series to the electrical signal source;
providing, by the electrical signal source, a first electric signal, the first electric signal comprising a periodic signal component, which is periodic with a predetermined period;
generating, by a first voltage and/or current sensor, a first sensor signal indicative of a voltage and/or current of the first electric signal;
generating, by a second voltage and/or current sensor, a second sensor signal indicative of a voltage across the powder handling device and/or a current through the powder handling device;
receiving, by a processing unit, the first and second sensor signals and determining a phase difference between the respective voltage of the first electric signal and the voltage across the powder handling device and/or between the respective current of the first electric signal and the current through the powder handling device; and
in response to a determination by the processing unit that the phase difference is below a predetermined threshold, outputting an output signal indicative of a mechanical contact between the moving part and the non-moving part of the powder handling device.
